(19) United States
(12) Patent Application Publication
(10) Pub. No.: US 2026/0243818 A1
(43) Pub. Date: Aug. 20, 2026

(54) SEMICONDUCTOR DEVICE

(71) Applicant: SONY SEMICONDUCTOR SOLUTIONS CORPORATION, Kanagawa (JP)

(72) Inventors: Hitoshi OKANO, Kanagawa (JP); Yuta NISHIOKA, Kanagawa (JP); Masanari YAMAGUCHI, Tokyo (JP)

(73) Assignee: SONY SEMICONDUCTOR SOLUTIONS CORPORATION, Kanagawa (JP)

(21) Appl. No.: 19/160,557

(22) PCT Filed: Feb. 20, 2024
(86) PCT No.: PCT/JP2024/005914

§ 371 Date: Aug. 28, 2025

(30) Foreign Application Priority Data
Mar. 8, 2023 (JP) 2023-035872

(51) Int. Cl. G01R 31/28; H10F 39/00

(52) U.S. Cl. CPC G01R 31/2829; G01R 31/2884; H10F 39/804; H10F 39/809; H10F 39/811

(57) ABSTRACT

The present disclosure relates to a semiconductor device that makes it possible to implement DUT measurement of a semiconductor device that is mounted even on a chip-stacked wafer of a CoW structure. Logic chips each including a singulated signal processing circuit, a singulated memory circuit, or the like are stacked on a wafer on which a plurality of imaging elements have been formed, a terminal is formed on the surface of a scribe that is a portion to be cut at a time of singulation, a connection wiring that connects the terminal on the surface of the scribe and a DUT of the Logic chip is formed between the wafer and the Logic substrate, and the terminal is connected with a probe to implement the DUT measurement without singulation. The present disclosure is applicable to a semiconductor device.

### TECHNICAL FIELD

The present disclosure relates to a semiconductor device, and, more particularly, to a semiconductor device that enables Device Under Test (DUT) measurement at a terminal provided on a surface of a scribe even in a Chip On Wafer (CoW) structure.

### BACKGROUND ART

As a technique of manufacturing a semiconductor device such as a solid-state imaging device, there is generally known a technique of manufacturing a semiconductor device by bonding pixel chips each including a solid-state imaging element, and Logic chips such as signal processing circuits or memory circuits in a wafer state, and stacking the pixel chips and the Logic chips in a Wafer on Wafer (WoW) structure.

When the solid-state imaging device is manufactured in the stacked state in the WoW structure as described above, a plurality of the solid-state imaging devices stacked in the WoW structure are singulated as final products by a dicing blade, and Device Under Test (DUT) measurement is performed for the purpose of process assurance in the state before singulation, that is, in the state of the WoW structure.

DUT measurement is test measurement for checking operating states of Logic chips such as signal processing circuits or memory circuits. More specifically, in the WoW structure before singulation, a Device Under Test (DUT) connected to the Logic chip such as the signal processing circuit or the memory circuit is electrically connected with an inspection device, with a probe being interposed therebetween, whereby the inspection device performs test measurement to check the operating states.

In the WoW structure, the DUT is disposed in a region in which a scribe cut by a dicing blade is formed when the solid-state imaging devices are singulated. Furthermore, the DUT is connected with a measurement terminal (AL PAD) provided on the surface of the scribe, with a Back End of Line (BEOL) wiring such as Cu being interposed therebetween, and the terminal is connected with the inspection device, with the probe being interposed therebetween, to perform DUT measurement.

By the way, in recent years, to increase a circuit scale to be mounted in one chip and achieve higher functionality, there is proposed a Chip on Wafer (CoW) structure in which Logic chips obtained by singulating a Logic wafer are stacked on a semiconductor wafer, on which solid-state imaging elements have been formed, in addition to the above-described Wafer on Wafer (WoW) structure.

The CoW structure is a structure in which one or two stages of the singulated Logic chips are stacked on the wafer, on which pixel chips each including the solid-state imaging element have been formed.

In such a CoW structure, the DUT of the Logic chip is not necessarily stacked such that the DUT matches with the region in which the scribe has been formed on the wafer, on which the pixel chips each including the solid-state imaging element have been formed, and therefore may not be disposed at the same position as that of the terminal (AL PAD) formed on the surface of the scribe, hence it is not possible to electrically connect both of the DUT and the terminal, and it may not be possible to implement DUT measurement.

That is, in the case of the CoW structure, to implement the above-described DUT measurement, it is necessary to separately form and connect a wiring for connecting the DUT of the Logic chip and the terminal (AL PAD) formed on the surface of the scribe.

In this regard, there has been proposed a technique (PTL 1) of forming and connecting a wiring layer that electrically connects a scribe region and a chip region with a guard ring that is interposed therebetween.

Hence, it is conceivable to connect the DUT of the Logic chip in the above described CoW structure, and the AL PAD formed on the surface of the scribe by applying the technique according to PTL 1.

### CITATION LIST

### Patent Literature

PTL 1: JP 2012-204630A

### SUMMARY

### Technical Problem

However, the technique described in PTL 1 is a technique of forming a wiring layer during the same wafer process, and therefore cannot be applied to a technique of connecting a DUT of a Logic chip generated by a different wafer process, and a terminal (AL PAD) formed on the surface of the scribe on a wafer on which solid-state imaging elements have been formed.

Furthermore, when the Logic chip is stacked on a wafer on which the solid-state imaging elements have been formed, the Logic chip needs to be disposed to be in contact with the region, in which the scribe is formed, so as to connect the DUT of the Logic chip and the terminal (AL-PAD) formed on the surface of the scribe, and the degree of freedom in the arrangement positions of the Logic chips lowers.

Furthermore, when there is a slight error in arrangement of the Logic chips and, for example, the Logic chips are disposed overlapping the region in which the scribes have been formed, there has been a risk that the Logic chips interfere with a dicing blade and damages the dicing blade at a time of dicing.

Furthermore, when a plurality of Logic chips are stacked on the same layer on the wafer, on which the solid-state imaging elements have been formed, a layout, for instance, in which a second Logic chip is disposed between a first Logic chip and a region where the scribe is formed, prevents connection between the DUT of the first Logic chip and the terminal (AL PAD) formed on the surface of the scribe, due to interference of the second Logic chip.

With such a situation in view, the present disclosure implements DUT measurement in a CoW structure by enabling electrical connection between DUTs of Logic chips and terminals formed on the surfaces of scribes without lowering the degree of freedom of arrangement positions of the Logic chips in the CoW structure, in particular.

### Solution to Problem

A semiconductor device according to one aspect of the present disclosure is a semiconductor device including: a first semiconductor chip that includes an imaging element; a second semiconductor chip that is different from the first semiconductor chip; and a connection wiring that electrically connects an internal circuit, which is a circuit in the second semiconductor chip with a terminal outside the second semiconductor chip or an external circuit, which is a circuit outside the second semiconductor chip.

According to one aspect of the present disclosure, there are provided the first semiconductor chip that includes the imaging element, the second semiconductor chip that is different from the first semiconductor chip, and the connection wiring that electrically connects the internal circuit, which is the circuit in the second semiconductor chip, with the terminal outside the second semiconductor chip or the external circuit, which is the circuit outside the second semiconductor chip.

### BRIEF DESCRIPTION OF DRAWINGS

FIG. 1 is a view for explaining a WoW structure.

FIG. 2 is a view for explaining a CoW structure.

FIG. 3 is a view for explaining a reason why a Logic chip is disposed away from a scribe in the CoW.

FIG. 4 is a view for explaining the reason why the Logic chip in the CoW is disposed away from the scribe.

FIG. 5 is a view for explaining a chip stacked wafer related to manufacturing of a solid-state imaging device according to the preferred embodiment of the present disclosure.

FIG. 6 is a view for explaining a cross-sectional structure of the chip stacked wafer in FIG. 5.

FIG. 7 is a bird's-eye view for explaining a CC′ cross section in FIG. 6.

FIG. 8 is a view for explaining a manufacturing process of the solid-state imaging device according to the present disclosure.

FIG. 9 is a view for explaining the manufacturing process of the solid-state imaging device according to the present disclosure.

FIG. 10 is a view for explaining a first modified example of the present disclosure.

FIG. 11 is a view for explaining a second modified example of the present disclosure.

FIG. 12 is a view for explaining a third modified example of the present disclosure.

FIG. 13 is a view for explaining a fourth modified example of the present disclosure.

FIG. 14 is a view for explaining a fifth modified example of the present disclosure.

FIG. 15 is a view for explaining a sixth modified example of the present disclosure.

FIG. 16 is a view for explaining a seventh modified example of the present disclosure.

FIG. 17 is a view for explaining an eighth modified example of the present disclosure.

FIG. 18 is a view for explaining a ninth modified example of the present disclosure.

FIG. 19 is a view for explaining a tenth modified example of the present disclosure.

### DESCRIPTION OF EMBODIMENTS

A preferred embodiment of the present disclosure will be described in detail below with reference to the accompanying drawings. Note that, in the present specification and the drawings, components employing substantially the same functional configurations will be denoted by the same reference numerals, and repeated descriptions thereof will be omitted.

The embodiment for carrying out the present technique will be described hereinafter. The descriptions will be given in the following order.
1. WoW Structure
2. CoW Structure
3. Preferred Embodiment
4. First Modified Example
5. Second Modified Example
6. Third Modified Example
7. Fourth Modified Example
8. Fifth Modified Example
9. Sixth Modified Example
10. Seventh Modified Example
11. Eighth Modified Example
12. Ninth Modified Example
13. Tenth Modified Example

### 1. WOW STRUCTURE

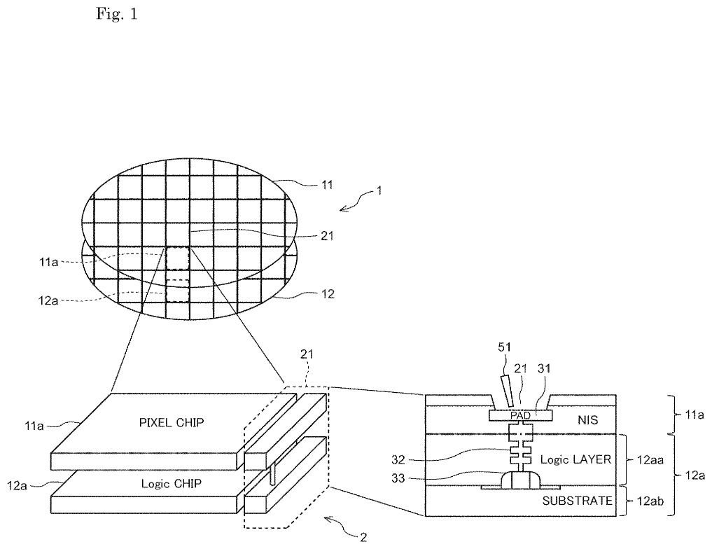

A Wafer on Wafer (WoW) structure will be described with reference to FIG. 1.

The Wafer on Wafer (WoW) structure is a structure of one form in a manufacturing process of a semiconductor device that is a final product. Note that, although description will be made below citing as an example a case where the semiconductor device that is the final product is a solid-state imaging device, the semiconductor device that is the final product may be other than the solid-state imaging device.

More specifically, when the semiconductor device that is the final product is a solid-state imaging device, as illustrated at the upper left part in FIG. 1, a stacked wafer 1 is generated by pasting a wafer 11 including a plurality of pixel chips formed thereon and each including a semiconductor element such as a solid-state imaging element, and a wafer 12 including a plurality of Logic chips such as signal processing circuits or memory circuits formed thereon in a state where the wafer 11 and the wafer 12 are aligned.

The structure of the stacked wafer 1 employing the configuration where these wafers 11 and 12 have been stacked is a Wafer on Wafer (WoW) structure.

In the wafer 11 constituting the stacked wafer 1 in FIG. 1, pixel chips 11a each including a solid-state imaging element are formed in respective square ranges in FIG. 1. Furthermore, Logic chips 12a each including a signal processing circuit or a memory circuit are formed in the respective square ranges of the wafer 12.

That is, in the stacked wafer 1, the wafer 11 on which a plurality of the pixel chips 11a have been formed and the wafer 12 on which a plurality of the Logic chips have been formed are pasted and stacked in a state where the respective pixel chips 11a and Logic chips 12a are aligned.

Scribes 21 expressed by solid lines extending in the horizontal direction and the vertical direction in FIG. 1 are formed around portions at which the pixel chips 11a and the Logic chips 12a have been formed on the stacked wafer 1. The scribe 21 is a portion to be cut by a dicing blade when a solid-state imaging device 2 that is a final product including the one pixel chip 11a and the one Logic chip 12a is singulated and cut out.

That is, the stacked wafer 1 is cut along the scribes 21 by the dicing blade, and thereby the solid-state imaging device 2 including the one pixel chip 11a and the one Logic chip 12a is singulated and cut out as the final product.

The lower left part in FIG. 1 illustrates a stacked structure of the solid-state imaging device 2 including the one pixel chip (NIS) 11a and the one Logic chip 12a on the stacked wafer 1. In this regard, the lower left part in FIG. 1 illustrates a state where the solid-state imaging device 2 is not cut out from the stacked wafer 1, and merely expresses the stacked structure of a portion corresponding to the one solid-state imaging device 2 in the stacked wafer 1.

As illustrated at the lower left part in FIG. 1, a Device Under Test (DUT) that is a test target device for checking operating states of the Logic chips is formed just below the scribes 21 of the pixel chips 11a.

More specifically, as illustrated at the lower right part in FIG. 1, a terminal (PAD) 31 that connects with a probe 51 for electrically connecting with an unillustrated inspection device for implementing DUT measurement is formed on the surface of the scribe 21 of the pixel chip 11a. Furthermore, the terminal 31 is connected to a DUT 33 of the Logic chip 12a with a wiring 32 interposed therebetween and formed in the Logic chip 12a.

As illustrated at the lower right part in FIG. 1, the Logic chip 12a includes a substrate 12ab and a Logic layer 12aa in which an unillustrated signal processing circuit or memory circuit, and the DUT are formed. Note that the lower right part in FIG. 1 is a cross-sectional side view of a range in which the scribe 21 is formed at the lower left part in FIG. 1.

The stacked wafer 1 of the WoW structure employs such a configuration, so that the probe 51 is connected to the terminal 31 in a state before the scribe 21 is cut and singulated by the dicing blade, and thereby the DUT 33 and the inspection device are electrically connected with the wiring 32 interposed therebetween and connected to the terminal to implement DUT measurement.

Consequently, it is possible to efficiently implement the DUT measurement of the plurality of solid-state imaging devices 2 formed on the stacked wafer 1 at a time.

### 2. COW STRUCTURE

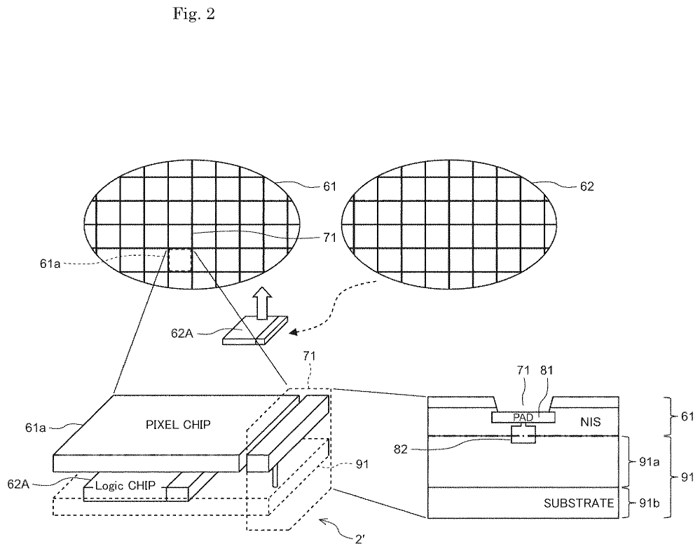

Next, the Chip on Wafer (CoW) structure will be described with reference to FIG. 2.

The Chip on Wafer (CoW) structure is also a structure of one form in the manufacturing process of the semiconductor device that is the final product similarly to the Wafer on Wafer (WoW) structure.

In the Chip on Wafer (CoW) structure, Logic chips 62A singulated from a wafer 62 on which a plurality of Logic chips such as signal processing circuits or memory circuits have been formed are pasted on a wafer 61 on which a plurality of pixel chips each including a semiconductor element such as a solid-state imaging element have been formed in a state where the Logic chips 62A are aligned.

The structure of the wafer 61 employing a configuration where the Logic chips 62A singulated and cut out from the wafer 62 are individually stacked at the respective positions of the pixel chips 61a of the wafer 61 is a Chip on Wafer (CoW) structure.

Also in the wafer 61 in FIG. 2, the pixel chips 61a each including a solid-state imaging element are formed in respective square ranges in FIG. 2. Furthermore, the Logic chips 62A each including a signal processing circuit or a memory circuit are formed in the respective square ranges of the wafer 62.

Furthermore, the respective pixel chips 61a and the Logic chips 62A singulated and cut out from the wafer 62 on which the plurality of Logic chips 62A have been formed are stacked and pasted on the wafer 61 on which the plurality of pixel chips 61a have been formed in a state where the pixel chips 61a and the Logic chips 62A are aligned.

Note that, since, in the CoW structure, the size of the Logic chip 62A does not generally match with the size of the pixel chip 61a, as illustrated at the lower left part in FIG. 2, a buried film is buried in a space around the Logic chip 62A at a time when the Logic chip 62A is pasted at a position meeting the pixel chip 61a. Thus, a Logic layer 91 including a buried layer 91a which includes the Logic chip 62A and a buried film, and a substrate 91b is formed.

In this case, scribes 71 expressed by solid lines extending in the horizontal direction and the vertical direction in FIG. 2 are formed around portions at which the pixel chips 61a have been formed on the wafer 61. The scribe 71 is a portion to be cut by the dicing blade when a solid-state imaging device 2′ that is a final product including the one pixel chip 61a and the one Logic chip 62A is singulated and cut out.

That is, the wafer 61 is cut along the scribes 71 by the dicing blade, and thereby the solid-state imaging device 2′ including the one pixel chip 61a and the one Logic chip 62A is singulated and cut out as the final product.

However, as illustrated at the lower left part in FIG. 2, the one pixel chip (NIS) 61a and the one Logic chip 62A in the wafer 61 do not necessarily have the same size as described above, and therefore even if, for example, a DUT is provided to part of the Logic chip 62A, it is not possible to form the DUT just below the scribe 71 of the pixel chip 61a.

Thus, as illustrated at the lower right part in FIG. 2, even if a terminal (PAD) 81 for connecting with the probe 51 for electrically connecting with the unillustrated inspection device for implementing DUT measurement is formed on the surface of the scribe 71 of the pixel chip 61a, and a component such as a wiring 82 is prepared, the terminal 81 and the DUT of the Logic chip 62A are misaligned and therefore cannot be connected.

Hence, it is conceivable to paste the DUT of this Logic chip 62A so as to be disposed just below the scribe 71 in the pixel chip 61a.

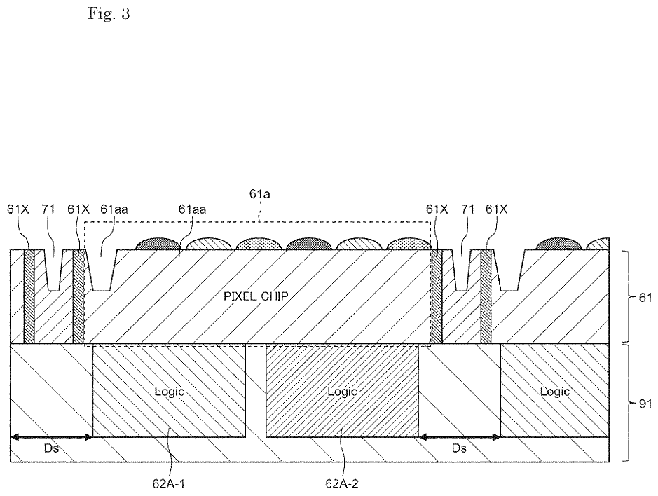

However, in a case where the pixel chip 61a includes guard rings 61X that are formed at portions around which the scribes 71 are formed, and each include a seal ring for maintaining water tightness as illustrated in FIG. 3, an interval between the guard rings 61X needs to be taken into account for the Logic chip 62A.

Hence, it is necessary to secure a space between the Logic chips 62A of the pixel chips 61a as indicated by, for example, distances Ds indicated by arrows in FIG. 3, and the DUT of the Logic chip 62A cannot be disposed just below the scribe 71 in the pixel chip 61a.

Note that FIG. 3 illustrates an example where two Logic chips 62A-1 and 62A-2 are pasted to the one pixel chip 61a.

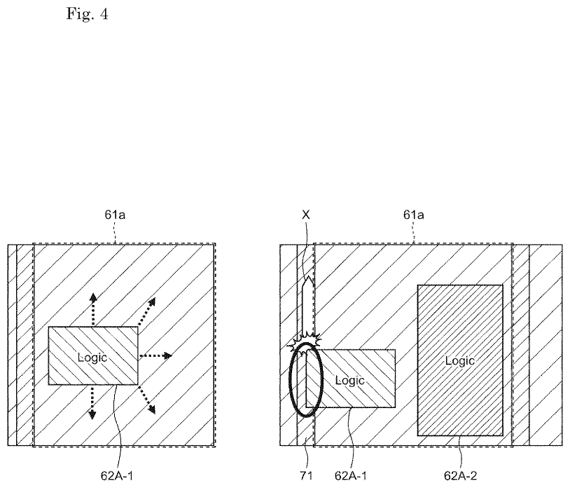

Furthermore, even if a configuration where the guard rings 61X are not provided is employed, if a configuration where the DUT of the Logic chip 62A is disposed just below the scribe 71 in the pixel chip 61a is employed, the Logic chip 62A can be disposed only at a position along the scribe 71 in the range in which the pixel chip 61a is provided as illustrated at the left part in FIG. 4, and therefore the degree of freedom of layout lowers.

Furthermore, although it is conceivable to employ a configuration where a DUT of the Logic chip 62A-1 is in contact with the scribe 71 as illustrated at the right part in FIG. 4, there is a risk that, in this case, if slight misalignment causes the Logic chip 62A-1 to interfere with the scribe 71, the Logic chip 62A-1 contacts a dicing blade X at a time of dicing and damages the dicing blade X.

Furthermore, as illustrated at the right part in FIG. 4, a DUT of a Logic chip 62A-2 cannot be configured such that the DUT is in contact with the scribe 71 because the Logic chip 62A-1 is provided between the DUT and the scribe 71.

As described above, the CoW structure generally employs a configuration where, even if the probe 51 is connected to the terminal 81 in a state before the terminal is cut and singulated on the surface of the scribe 71 by the dicing blade, the DUT and the inspection device cannot be electrically connected, and it is not realistic to perform DUT measurement before singulation.

Therefore, the present disclosure enables even the CoW structure to implement DUT measurement of Logic chips.

### 3. PREFERRED EMBODIMENT

### Configuration Example of Solid-State Imaging Device

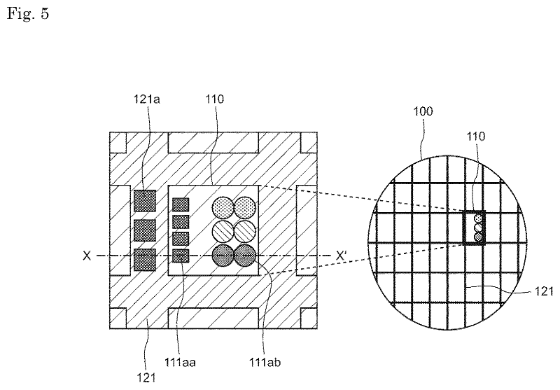

Next, a configuration example of the solid-state imaging device according to the present disclosure will be described with reference to FIGS. 5 to 7.

Note that the right part in FIG. 5 is a top view of a chip stacked wafer 100 including a plurality of solid-state imaging devices 110 formed therein and each including a wafer 101 on which pixel chips 111a each including a solid-state imaging element have been formed, and a Logic layer 102 formed by stacking a singulated Logic chip 112A on the one pixel chip 111a and burying the surroundings of the Logic chip 112A with a buried film 146.

Furthermore, the left part in FIG. 5 is an enlarged top view of the one solid-state imaging device 110 of the chip stacked wafer 100 at a time of completion.

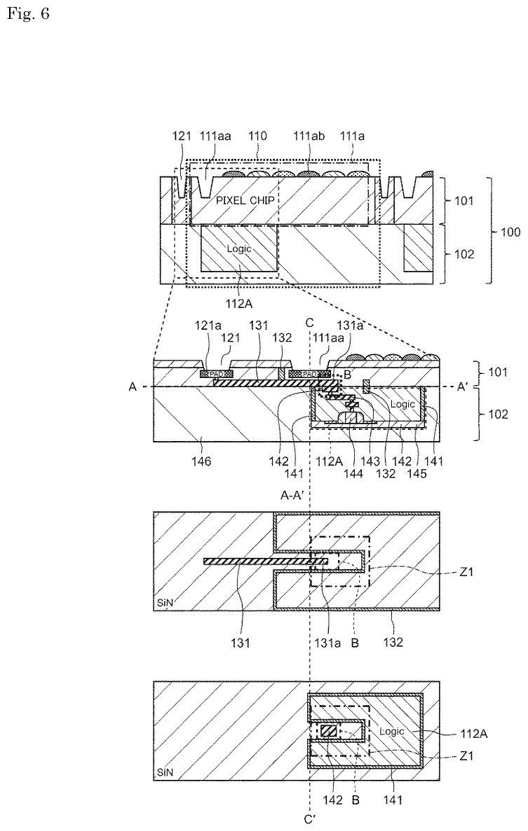

Furthermore, FIG. 6 is a cross-sectional side view of the solid-state imaging device 110 in which the uppermost stage is an XX′ cross-section in FIG. 5.

Furthermore, the second stage from the top in FIG. 6 is an enlarged view of a portion at which the Logic chip 112A has been stacked in the cross-sectional side view of the uppermost stage in FIG. 6, the third stage from the top in FIG. 6 is a cross-sectional view of the wafer 101 side in the AA′ cross-section of the second stage from the top in FIG. 6, and the fourth stage from the top in FIG. 6 is a cross-sectional view of the Logic layer 102 side in the AA′ cross-section of the second stage from the top in FIG. 6.

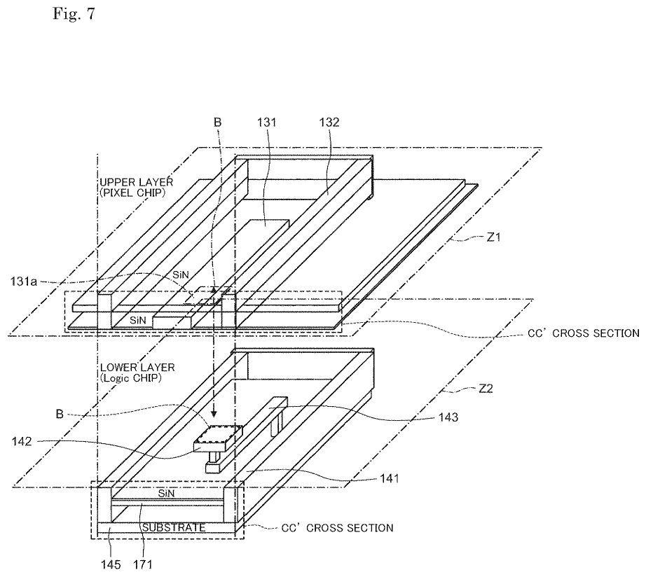

Furthermore, FIG. 7 is a bird's-eye view viewed from a CC′ cross-section side in the second stage to the fourth stage from the top in FIG. 6 of each of regions Z1 and Z2 existing near a range B surrounded by a dotted line in the second stage from the top in FIG. 6 and at positions corresponding to the third stage and the fourth stage in FIG. 6.

As illustrated in FIG. 5 and the uppermost stage and the second stage from the top in FIG. 6, the pixel chip 111a is provided with a terminal 111aa including a PAT for connecting with a probe for checking an operation of the pixel chip 111a. Furthermore, the pixel chip 111a is provided with a color filter 111ab on the incident surface of incident light that is the upper part in FIGS. 5 and 6.

Furthermore, as illustrated in FIG. 5 and the uppermost stage in FIG. 6, a scribe 121 is formed around the pixel chip 111a, and a terminal 121a including the PAT for connecting with the probe 51 in FIG. 1 for DUT measurement is formed on the surface of the scribe 121 on the left side of the pixel chip 111a in FIG. 5 and the uppermost stage in FIG. 6.

Furthermore, the terminal 121a is electrically connected with the left end part of a connection wiring 131 illustrated in FIG. 6 and provided on a boundary surface with respect to the Logic layer 102 in the wafer 101. The right end part of the connection wiring 131 is provided with a connection part 131a. The connection part 131a is connected with a connection part 142 provided in the Logic chip 112A in the Logic layer 102 as indicated by the range B surrounded by a dotted line in FIG. 6.

In the Logic chip 112A, a DUT 144 is formed on a substrate 145 and electrically connected with the connection part 142 with a wiring 143 interposed therebetween.

That is, the terminal 121a formed on the surface of the scribe 121 is electrically connected with the DUT 144 with the connection wiring 131, the connection part 131a, the connection part 142, and the wiring 143 interposed therebetween.

Consequently, by connecting the probe 51 of the unillustrated inspection device to the terminal 121a formed on the surface of the scribe 121, it is possible to electrically connect the DUT 144 and the unillustrated inspection device with the terminal 121a, the connection wiring 131, the connection part 131a, the connection part 142, and the wiring 143 interposed therebetween.

As a result, it is possible to implement DUT measurement of the solid-state imaging device 110 in a state of the chip stacked wafer 100 of the CoW structure as is, in other words, in a state before the solid-state imaging device 110 is singulated.

Furthermore, in the wafer 101, as illustrated in the third stage from the top in FIG. 6, in a range in which the pixel chip 111a has been formed, a guard ring 132 including a seal ring is formed so as to surround the entire range except for a range except the connection wiring 131.

Furthermore, as illustrated in FIG. 7, the connection wiring 131 includes water resistant layers 161 and 162 that are formed at the front stage and the rear stage with respect to the incident direction of the incident light, have water resistance to sandwich the connection wiring 131, and are made of, for example, silicon nitride (SiN), aluminum oxide (Al₂O₃), or the like. More specifically, the connection wiring 131 is formed in the insulating film surrounded by the water resistant layers 161 and 162 and the guard ring 132.

In this regard, as for the portion of the connection part 131a of the connection wiring 131, the water resistant layer 162 is not formed in a range facing the connection part 142 to enable electrical connection with the connection part 142 connected to the wiring 143 formed on the Logic chip 112A, and the connection part 131a is partially exposed.

Furthermore, in the Logic layer 102, as illustrated in the fourth stage from the top in FIG. 6, in a range in which the Logic chip 112A has been formed, a guard ring 141 including a seal ring is formed so as to surround the entire range except for a range in which the connection part 142 has been formed.

Furthermore, a water resistant layer 171 made of silicon nitride (SiN) or aluminum oxide (Al₂O₃) having water resistance is formed between the connection part 142 and the wiring 143. In this regard, the connection part 142 and the wiring 143 are electrically connected, and the water resistant layer 171 is not formed at a connection portion of the connection part 142 and the wiring 143.

According to such a configuration, the terminal 121a employs a configuration where, although the terminal 121a is electrically connected with the DUT 144 with the connection wiring 131, the connection part 131a, the connection part 142, and the wiring 143 interposed therebetween, the pixel chip 111a and the Logic chip 112A each have water resistance thanks to the guard rings 132 and 141 and the water resistant layers 161, 162, and 171.

That is, the chip stacked wafer 100 including the Logic layer 102 and the wafer 101 of the CoW structure according to the present disclosure employs a configuration where the terminals 121a formed on the surfaces of the scribes 121 in the plurality of formed pixel chips 111a are connected with the DUTs 144 of the Logic chips 112A with the connection wirings 131, the connection part 131a, the connection part 142, and the wiring 143 interposed therebetween.

Consequently, by connecting the probe of the inspection device to the terminal 121a formed on the surface of each scribe 121 without singulating the solid-state imaging device 110 formed on the chip stacked wafer 100, electrical connection thereof with the DUT 144 of the Logic chip 112A is enabled, and DUT measurement can be implemented.

Furthermore, when the connection wiring 131 is formed, the guard ring 132 including the seal ring in the pixel chip 111a, the water resistant layers 161 and 162, and the guard ring 141 including the seal ring in the Logic chip 112A, and the water resistant layer 171 enables the pixel chip 111a and the Logic chip 112A to secure sufficient water resistance.

Furthermore, the connection wiring 131 can be wired at various positions on the pixel chip 111a as long as the above-described guard ring 132 and water resistant layers 161 and 162 are provided, and the connection part 131a can be disposed at various positions, so that it is possible to increase the degree of freedom of layout of the Logic chip 112A in the pixel chip 111a.

At this time, for example, even if another Logic chip is provided between the scribe 121 and the Logic chip 112A of interest, it is possible to electrically connect the terminal 121a and the DUT 144 by bypassing a route of the connection wiring 131, and, in this regard, it is also possible to increase the degree of freedom of layout.

### Manufacturing Process of Solid-State Imaging Device

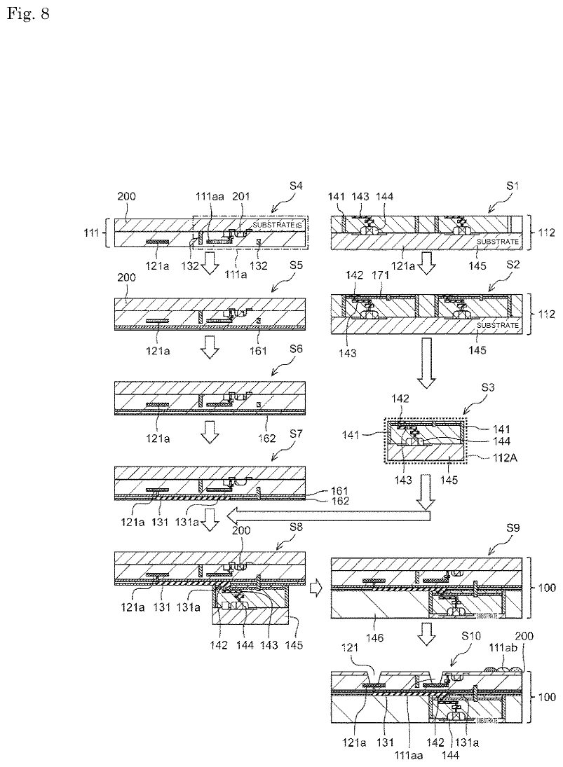

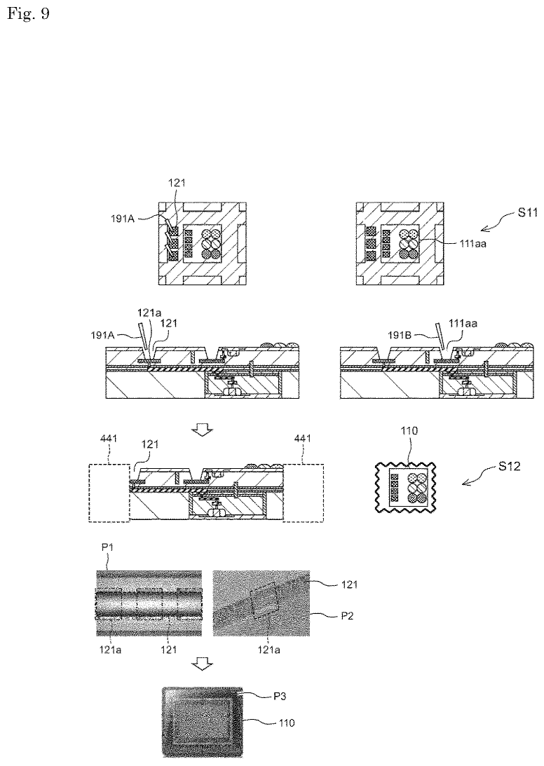

Next, the manufacturing process of the solid-state imaging device 110 according to the present disclosure will be described with reference to FIGS. 8 and 9.

In step S1 (FIG. 8), as illustrated in the uppermost stage on the right side in FIG. 8, a wafer 112 including the plurality of Logic chips 112A formed thereon and each including the DUT 144 and the wiring 143, and the guard ring 141 on the substrate 145 is generated.

In step S2, as illustrated in the second stage from the top on the right side in FIG. 8, the connection part 142 is formed in each wiring 143 of the plurality of Logic chips 112A of the wafer 112.

In step S3, the wafer 112 is singulated in units of the Logic chips 112A as illustrated in the third stage from the top on the right side in FIG. 8.

In step S4, as illustrated in the uppermost stage on the left side in FIG. 8, a wafer 111 including the plurality of pixel chips 111a formed thereon and each including a test device 201 of the pixel chip 111a, the terminal 111aa connected with the test device 201, and the terminal 121a formed at the position of the scribe 121 is generated.

Note that the test device 201 and the terminal 111aa are formed on the inner side of the guard ring 132, and the terminal 121a is formed on the outer side of the guard ring 132. Furthermore, in FIG. 8, the wafer 111 is displayed upside down. Hence, although a substrate 200 is illustrated in the upper stage, display is illustrated upside down during actual processing and the substrate 200 is located in the lower stage.

In step S5, the water resistant layer 161 made of silicon nitride (SiN) is formed on the upper surface of the wafer 111 as illustrated in the second stage from the top on the left side in FIG. 8.

In step S6, the water resistant layer 162 is further formed on the water resistant layer 161 made of silicon nitride (SiN) on the upper surface of the wafer 111 as illustrated in the third stage from the top on the left side in FIG. 8.

In step S7, as illustrated in the fourth stage from the top on the left side in FIG. 8, part of the water resistant layers 161 and 162 are peeled off such that the connection wiring 131 is electrically connected with the terminal 121a to form the connection wiring 131.

Note that the processing in above-described steps S1 to S3 and the processing in steps S4 to S7 may be performed in reverse order or may be performed in parallel.

In step S8, as illustrated in the fifth stage from the top on the left side in FIG. 8, the singulated Logic chip 112A is stacked on each pixel chip 111a of the wafer 111. At this time, the connection part 131a of the connection wiring 131 of the pixel chip 111a and the connection part 142 of the Logic chip 112A are stacked in a state where the connection part 131a and the connection part 142 are electrically connected.

In step S9, as illustrated in the fourth stage from the top on the right side in FIG. 8, the substrate 145 of the stacked Logic chip 112A is made thinner, the buried film 146 is formed around the Logic chip 112A, and then the chip stacked wafer 100 is finished.

In step S10, as illustrated in the fifth stage from the top on the right side in FIG. 8, the substrate 200 is made thinner, the scribes 121 are formed, the terminals 121a are opened, the terminal 111aa is opened, and the color filter 111ab is formed. Consequently, the plurality of solid-state imaging devices 110 are finished on the chip stacked wafer 100. That is, the terminal 121a and the DUT 144 of the Logic chip 112A are electrically connected, and DUT measurement can be performed.

In step S11 (FIG. 9), as illustrated in the left parts of the uppermost stage and the second stage from the top in FIG. 9, the terminal 121a is connected with a probe 191A, and thereby the unillustrated inspection device and the DUT 144 of the Logic chip 112A are electrically connected to perform DUT measurement.

Furthermore, as illustrated in the right parts of the uppermost stage and the second stage from the top in FIG. 9, the terminal 111aa is continuously connected with a probe 191B, and thereby the unillustrated inspection device and the test device 201 of the pixel chip 111a are electrically connected to implement test measurement of the pixel chip 111a.

In step S12, as illustrated in the left figure and the right figure of the third stage from the top in FIG. 9, the chip stacked wafer 100 is cut along the scribe 121 by the dicing blade to singulate each of the solid-state imaging devices 110 to finish the solid-state imaging device 110 as a product.

Note that an image P1 in the fourth stage in FIG. 9 is a direct facing surface image of a state where the scribe 121 is formed in the horizontal direction in FIG. 9 and the three terminals 121a are formed on the surface of the scribe 121, and an image P2 is a bird's-eye image obtained by enlarging the terminals 121a formed on the scribe 121. Furthermore, an image P3 in the fifth stage in FIG. 9 is an image of the solid-state imaging device 110 as a packaged finished product.

### 4. FIRST MODIFIED EXAMPLE

Although the example has been described above where the water resistant layers 161 and 162 are formed so as to sandwich the connection wiring 131, the water resistant layers 161 and 162 may be formed at other positions and, for example, water resistant layers may be formed to surround the back surface side of the pixel chip 111a and the entire Logic chip 112A.

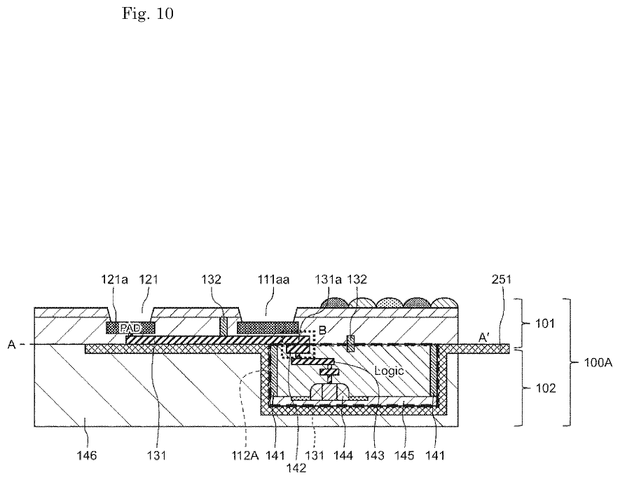

FIG. 10 illustrates a configuration example of a chip stacked wafer 100A in which water resistant layers are formed so as to surround the back surface side of the pixel chips 111a and the entire Logic chip 112A. Note that, in FIG. 10 and subsequent figures, components having the same functions as those of the chip stacked wafer 100 described with reference to FIGS. 5 to 7 are denoted by the same reference signs, and description thereof will be omitted as appropriate.

In FIG. 10, a water resistant layer 251 is formed that surrounds the back surface side of the pixel chip 111a with respect to the incident direction of incident light and the entire side surface and back surface sides of the Logic chip 112A and is made of, for example, silicon nitride or the like.

Note that the water resistant layer 251 in FIG. 10 may be formed in a process before the buried film 146 is formed when the Logic chip 112A is stacked on the wafer 101.

The chip stacked wafer 100 of the CoW structure employing the above-described configuration can also implement DUT measurement. Furthermore, the water resistant layer 251 in FIG. 10 can provide stronger water resistance.

### 5. SECOND MODIFIED EXAMPLE

Although the example has been described above where the DUT 144 in the Logic chip 112A is formed in the guard ring 141, the DUT 144 may be formed on the outer side of the guard ring.

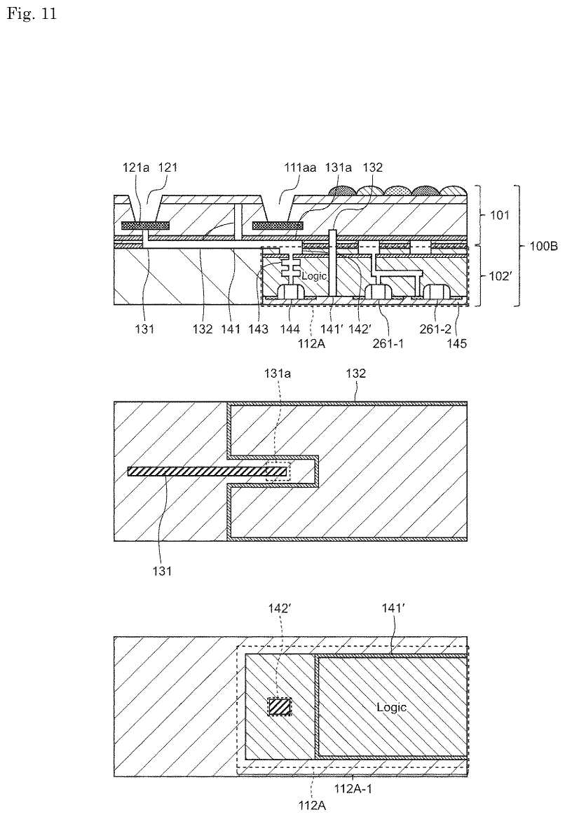

FIG. 11 illustrates a configuration example of a chip stacked wafer 100B in which the DUT 144 has been formed on the outer side of a guard ring.

As illustrated in the uppermost stage in FIG. 11, the chip stacked wafer 100B includes the wafer 101 and a Logic layer 102′. In the Logic chip 112A of the Logic layer 102′, the DUT 144 is formed on the outer side of a guard ring 141′ corresponding to the guard ring 141.

Furthermore, as illustrated in the second stage from the top in FIG. 11, the configuration of the pixel chip 111a in the wafer 101 is similar to the configuration illustrated in FIG. 6.

However, as illustrated in the uppermost stage in FIG. 11, since the DUT 144 is provided on the outer side of the guard ring 141′, a connection part 142′ connected with the DUT 144, with the wiring 143 being interposed therebetween, is formed on the outer side of the guard ring 141′ as illustrated in the third stage from the top in FIG. 11.

The chip stacked wafer 100B of the CoW structure employing the above-described configuration can also implement DUT measurement.

### 6. THIRD MODIFIED EXAMPLE

Although the example has been described above where the DUT 144 of the Logic chip 112A is formed on the outer side of the guard ring 141′, the DUT 144 may be formed by being further surrounded by a seal ring on the inner side of the guard ring 141.

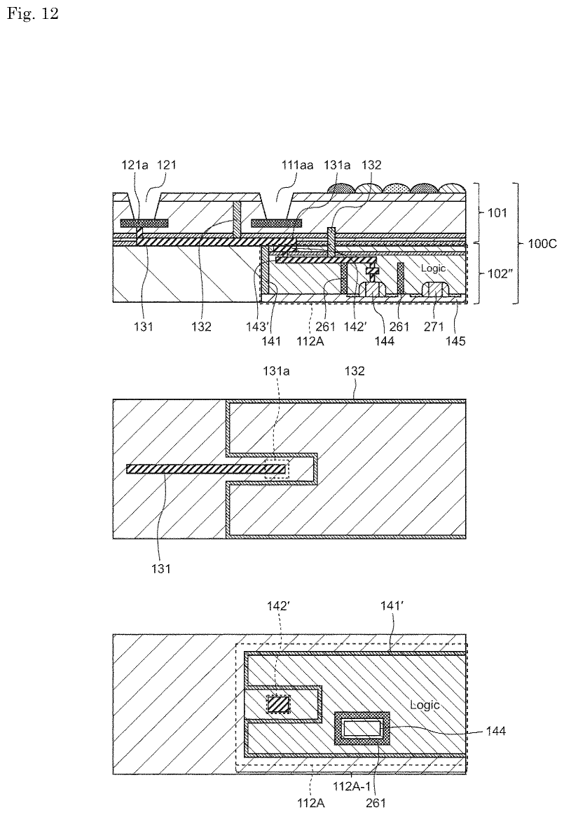

FIG. 12 illustrates a configuration example of a chip stacked wafer 100C in which the DUT 144 is formed on the inner side of the guard ring 141 and is surrounded by a seal ring.

That is, the chip stacked wafer 100C in FIG. 12 includes the wafer 101 and a Logic layer 102″. In the Logic layer 102″, the DUT 144 is disposed by being surrounded by the guard ring 141 and further surrounded by a seal ring 261 having water resistance. The seal ring 261 is formed in a Back End of Line (BEOL) layer. The connection part 142′ and the DUT 144 are electrically connected with a wiring 143′ interposed between and corresponding to the wiring 143.

Note that, in FIG. 12, an internal circuit 271 is formed on the substrate 145 in addition to the DUT 144 on the substrate. The internal circuit 271 is formed on the inner side of the guard ring 141, yet on the outer side of the seal ring 261.

According to the above-described configuration, the chip stacked wafer 100C of the CoW structure can also implement DUT measurement.

### 7. FOURTH MODIFIED EXAMPLE

The configuration has been described above where the connection wiring 131 is formed at the boundary between the wafer 101 and the Logic layer 102, the terminal 121a is electrically connected with the DUT 144 with the connection wiring 131, the connection part 131a, the connection part 142′, and the wiring 143 interposed therebetween.

However, the connection wiring 131 may be disposed at a position other than the boundary between the wafer 101 and the Logic layer 102, and may be provided on the back surface side of the Logic chip 112A viewed from, for example, the incident direction of incident light.

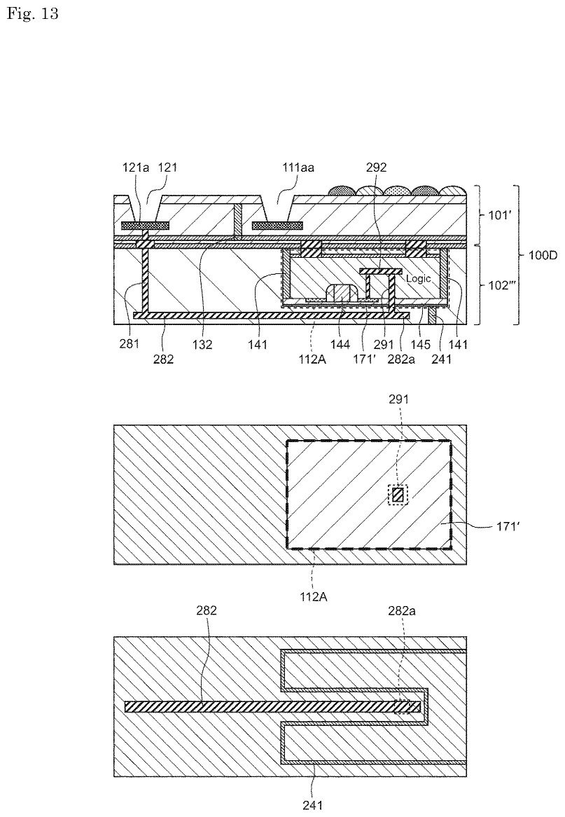

FIG. 13 illustrates a configuration example of a chip stacked wafer 100D in which a connection wiring is formed on the back surface side of the Logic chip 112A. The chip stacked wafer 100D includes a wafer 101′ and a Logic layer 102′″. Note that, in FIG. 13, the uppermost stage illustrates a configuration example of the chip stacked wafer 100D. The chip stacked wafer 100D is a cross-sectional side view of the wafer 101′ and the Logic layer 102′″, the second stage from the top illustrates a configuration example of the back surface side of the Logic chip 112A, and the third stage from the top is a cross-sectional view of a layer in which a connection wiring 282 is formed.

That is, the connection wiring 131 is not wired at the boundary between the wafer 101′ and the Logic layer 102′″, and, instead of the connection wiring 131, a corresponding connection wiring 282 is formed on the back surface side of the Logic chip 112A of the Logic layer 102′″.

The connection wiring 282 has the left end part in FIG. 13 connected with the terminal 121a with a wiring 281 interposed therebetween and including a Through Silicon Via (TSV).

Furthermore, a connection part 282a is formed at the right end part of the connection wiring 282 in FIG. 13, and connected with a connection part 291 formed on the back surface side of the Logic chip 112A. The connection part 291 is electrically connected with the DUT 144 with a wiring 292 interposed therebetween and including the TSV. Hence, the terminal 121a is connected with the DUT 144 with the wiring 281, the connection wiring 282, the connection part 282a, the connection part 291, and the wiring 292 interposed therebetween.

Furthermore, as illustrated in the second stage in FIG. 13, a water resistant layer 171′ that corresponds to the water resistant layer 171, and is made of silicon nitride or the like is formed on the back surface side of the Logic chip 112A, and is configured to have water resistance. However, a portion of the water resistant layer 171′ at which the connection part 291 is formed is configured such that the connection part 291 is exposed, so that the connection part 291 can be electrically connected with the connection part 282a in this configuration.

According to the above-described configuration, the chip stacked wafer 100D having the CoW structure in FIG. 13 can also implement DUT measurement.

### 8. FIFTH MODIFIED EXAMPLE

Although the chip stacked wafer 100 of the CoW structure including the two layers of the wafer 101 and the Logic layer 102 has been described, the chip stacked wafer 100 may include three layers.

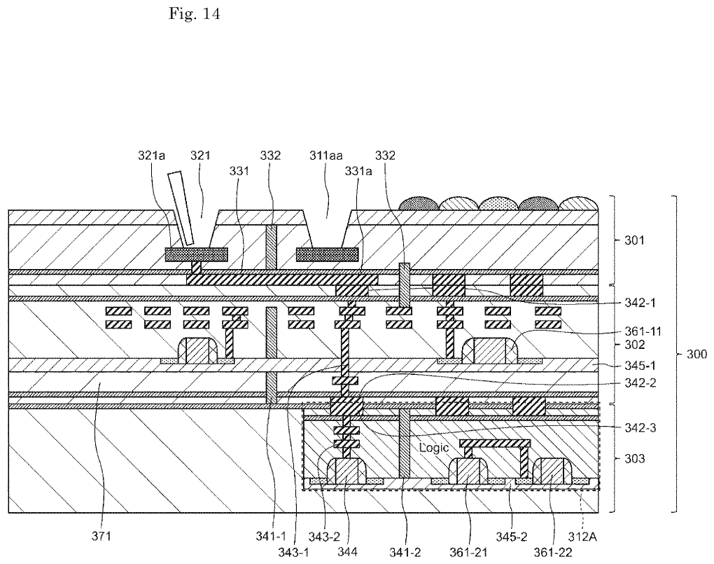

FIG. 14 illustrates a configuration example of a chip stacked wafer 300 of a CoW structure of three layers including a wafer 301, an intermediate layer 302, and a Logic layer 303. Note that the intermediate layer 302 may be a wafer on which a plurality of semiconductor chips have been formed, or a semiconductor layer formed by stacking singulated semiconductor chips.

Note that the wafer 301 is a component corresponding to the wafer 101, and scribes 321, terminals 321a, guard rings 332, terminals 321aa, connection wirings 331, and connection parts 331a of the wafer 301 are components corresponding to the scribes 121, the terminals 121a, the guard rings 132, the terminals 121a, the connection wirings 131, and the connection parts 131a of the wafer 101, respectively.

Furthermore, in the intermediate layer 302, an internal circuit 361-11 is formed on a substrate 345-1 and a guard ring 341-1 is formed. Furthermore, in the intermediate layer 302, a connection part 342-1, a wiring 343-1, and a connection part 342-2 are formed. The connection parts 342-1 and 342-2 are respectively formed at the both end parts of the wiring 343-1. The connection part 342-1 is connected with the connection part 331a of the connection wiring 331. The connection part 342-2 is connected with the connection part 342-3 of the Logic layer 303.

An inter-layer insulating film 371 is formed between the substrate 345-1 of the intermediate layer 302 and the Logic layer 303.

Furthermore, the Logic layer 303 includes a Logic chip 312A, a guard ring 341-2 is formed on the Logic chip 312A, internal circuits 361-21 and 361-22 are formed on the substrate 345-2 and on the inner side of the guard ring 341-2, and a DUT 344 is formed on the outer side of the guard ring 341-2. Furthermore, the DUT 344 is connected with a connection part 342-3 with a wiring 343-2 interposed therebetween.

That is, according to such a configuration, the terminal 321a is connected with the DUT 344 with the connection wiring 331, the connection part 331a, the connection part 342-1, the wiring 343-1, the connection part 342-2, the connection part 342-3, and the wiring 343-2 interposed therebetween.

As a result, the chip stacked wafer 301 having the CoW structure of the three layers in FIG. 14 can also electrically connect the DUT 344 of the Logic chip 312A and the unillustrated inspection device by connecting the probe to the terminal 321a, and consequently can implement DUT measurement.

### 9. SIXTH MODIFIED EXAMPLE

The example has been described above where, in the chip stacked wafer 300 of the CoW structure of the three layers including the wafer 301, the intermediate layer 302, and the Logic layer 303, the connection wiring 331 is formed at a boundary between the wafer 301 and the intermediate layer 302, and the terminal 321a and the DUT 344 of the Logic chip 312A are electrically connected to implement DUT measurement.

However, the connection wiring 331 may be formed at other than the boundary between the wafer 301 and the intermediate layer 302, and may be formed at, for example, the boundary between the intermediate layer 302 and the Logic layer 303.

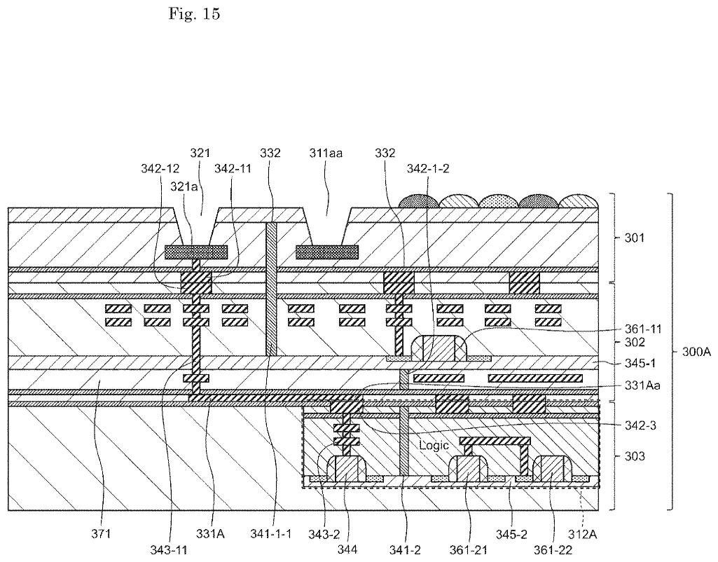

FIG. 15 illustrates a configuration example of a chip stacked wafer in which the connection wiring 331 is formed between the intermediate layer 302 and the Logic layer 303.

In a chip stacked wafer 300A in FIG. 15, a connection wiring 331A is formed at the boundary between the intermediate layer 302 and the Logic layer 303 instead of the connection wiring 331 in the chip stacked wafer 300 in FIG. 14.

Furthermore, a connection part 342-11 to be connected with the terminal 321a is formed on the wafer 301, and a wiring 343-11 is formed in the intermediate layer 302, and has an end part illustrated on the upper side in FIG. 15 and connected with the connection part 342-11 with a connection part 342-12 interposed therebetween, and an end part illustrated on the lower side in FIG. 15 and electrically connected with the left end part of the connection wiring 331A in FIG. 15.

Furthermore, a connection part 331Aa is formed at the right end part of the connection wiring 331A in FIG. 15, is connected with the connection part 342-3 of the Logic chip 312A, and is connected with the DUT 344 with the wiring 343-2 interposed therebetween.

According to such a configuration, in the chip stacked wafer 300A in FIG. 15, the terminal 321a is connected with the connection part 342-11, and the connection part 342-11 is connected with the connection part 342-12 of the wiring 343-11. Furthermore, the wiring 343-11 is connected with the left end part of the connection wiring 331A in FIG. 15, and the connection part 331Aa at the left end part in FIG. 15 is connected with the connection part 342-3 of the Logic chip 312A.

That is, according to such a configuration, the terminal 321a is connected with the DUT 344 with the connection part 342-11, the connection part 342-12, the wiring 343-11, the connection wiring 331A, the connection part 331Aa, the connection part 342-3, and the wiring 343-2 interposed therebetween.

As a result, the chip stacked wafer 301A having the CoW structure of the three layers in FIG. 15 can also electrically connect the DUT 344 of the Logic chip 312A and the unillustrated inspection device by connecting the probe to the terminal 321a, and consequently can implement DUT measurement.

### 10. SEVENTH MODIFIED EXAMPLE

The example has been described above where, in the chip stacked wafer 300 of the CoW structure of the three layers including the wafer 301, the intermediate layer 302, and the Logic layer 303, the connection wiring 331A is formed at the boundary between the intermediate layer 302 and the Logic layer 303, and the terminal 321a and the DUT 344 of the Logic chip 312A are electrically connected to implement DUT measurement.

However, the connection wiring 331 may be formed at other than the boundary between the intermediate layer 302 and the Logic layer 303 and may be formed in, for example, the inter-layer insulating film 371 in the intermediate layer 302.

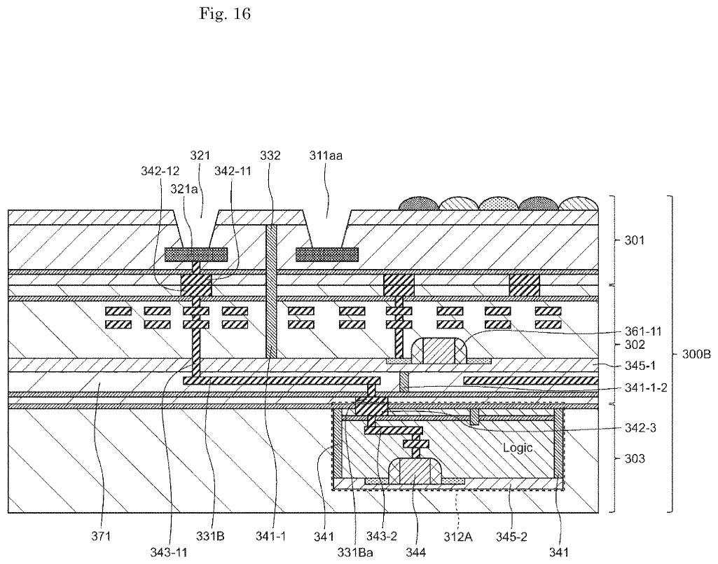

FIG. 16 illustrates a configuration example of a chip stacked wafer in which the connection wiring 331 is formed in the inter-layer insulating film 371 of the intermediate layer 302.

In a chip stacked wafer 300B in FIG. 16, a connection wiring 331B is formed in the inter-layer insulating film 371 of the intermediate layer 302 instead of the connection wiring 331A in the chip stacked wafer 300A in FIG. 15.

According to such a configuration, in the chip stacked wafer 300B in FIG. 16, the terminal 321a is connected with the connection part 342-11, and the connection part 342-11 is connected with the wiring 343-11 with the connection part 342-12 interposed therebetween. Furthermore, the wiring 343-11 is connected with the left end part of the connection wiring 331B in FIG. 16, and a connection part 331Ba of the right end part of the connection wiring 331B in FIG. 16 is connected with the connection part 342-3 of the Logic chip 312A.

That is, according to such a configuration, the terminal 321a is connected with the DUT 344 with the connection part 342-11, the connection part 342-12, the wiring 343-11, the connection wiring 331B, the connection part 331Ba, the connection part 342-3, and the wiring 343-2 interposed therebetween.

As a result, a chip stacked wafer 301B having the CoW structure of the three layers in FIG. 16 can also electrically connect the DUT 344 of the Logic chip 312A and the unillustrated inspection device by connecting the probe to the terminal 321a, and consequently can implement DUT measurement.

### 11. EIGHTH MODIFIED EXAMPLE

The connection wiring 331 may be formed at a position other than the boundary between the intermediate layer 302 and the Logic layer 303 or in the inter-layer insulating film 371 in the intermediate layer 302 and may be formed on, for example, the substrate 345-1 of the intermediate layer 302.

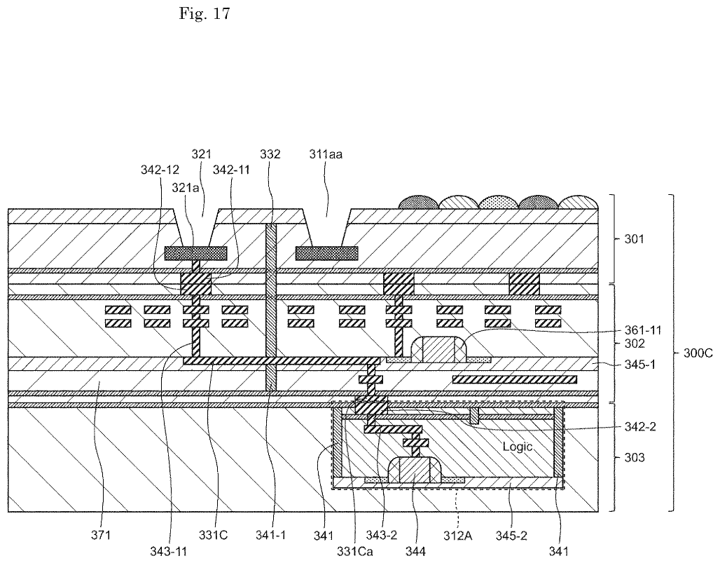

FIG. 17 illustrates a configuration example of a chip stacked wafer in which the connection wiring 331 is formed in the substrate 345-1 of the intermediate layer 302.

In a chip stacked wafer 300C in FIG. 17, a connection wiring 331C is formed on the substrate 345-1 of the intermediate layer 302 instead of the connection wiring 331B in the chip stacked wafer 300B in FIG. 16.

According to such a configuration, in the chip stacked wafer 300C in FIG. 17, the terminal 321a is connected with the connection part 342-11, and the connection part 342-11 is connected with the wiring 343-11 with the connection part 342-12 interposed therebetween. Furthermore, the wiring 343-11 is connected with the left end part of the connection wiring 331C in FIG. 17, and a connection part 331Ca at the right end part of the connection wiring 331C in FIG. 17 is connected with the connection part 342-3 of the Logic chip 312A.

That is, according to such a configuration, the terminal 321a is connected with the DUT 344 with the connection part 342-11, the connection part 342-12, the wiring 343-11, the connection wiring 331C, the connection part 331Ca, the connection part 342-3, and the wiring 343-2 interposed therebetween.

As a result, a chip stacked wafer 301C having the CoW structure of the three layers in FIG. 17 can also electrically connect the DUT 344 of the Logic chip 312A and the unillustrated inspection device by connecting the probe to the terminal 321a, and consequently can implement DUT measurement.

### 12. NINTH MODIFIED EXAMPLE

The example has been described above where, in the chip stacked wafer 300 of the CoW structure of the three layers including the wafer 301, the intermediate layer 302, and the Logic layer 303, the terminal 321a and the DUT 344 of the Logic chip 312A are electrically connected to implement DUT measurement.

However, if a plurality of the Logic chips 312A are further stacked, the plurality of Logic chips 312A may be connected by a connecting wiring to be able to be electrically connected with each other.

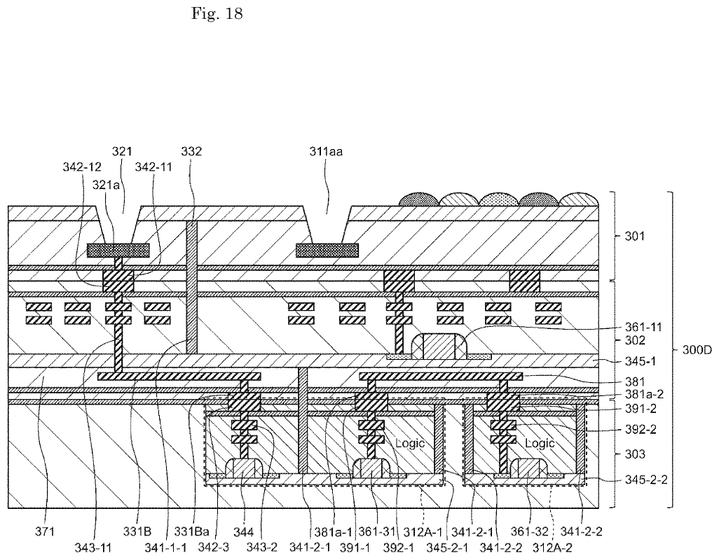

FIG. 18 illustrates a configuration example of a chip stacked wafer in which the connection wiring that connects the two Logic chips 312A is formed in the inter-layer insulating film 371 of the intermediate layer 302.

A chip stacked wafer 300D in FIG. 18 illustrates an example where two Logic chips 312A-1 and 312A-2 are stacked in the Logic layer 303 of the chip stacked wafer 300B in FIG. 16, and are connected with each other by a connection wiring 381.

Note that the Logic chip 312A-1 among the Logic chips 312A-1 and 312A-2 includes the DUT 344 associated with the Logic chip 312A in FIG. 16, and employs the same configuration where the terminal 321a is electrically connected with the DUT 344 by connecting the probe to the terminal 321a, and therefore description of the configuration will be omitted. In this regard, the difference in FIG. 18 is that the DUT 344 is formed on the outer side of a guard ring 341-2-1.

In addition to the function of the Logic chip 312A in FIG. 16, the Logic chip 312A-1 includes an internal circuit 361-31 that is formed on an the inner side of the guard ring 341-2-1 and on a substrate 345-2-1, and is connected with a connection part 391-1, with a wiring 392-1 being interposed therebetween.

The Logic chip 312A-2 includes a guard ring 341-2-2, includes an internal circuit 361-32 that is formed on the inner side of the guard ring 341-2-2 and on a substrate 345-2-2, and is connected with the connection part 391-2, with a wiring 392-2 being interposed therebetween.

The connection wiring 381 is formed in the inter-layer insulating film 371 of the intermediate layer 302, and has both end parts at which connection parts 381a-1 and 381a-2 are formed. Furthermore, the connection part 381a-1 is connected with the connection part 391-1 of the Logic chip 312A-1, and the connection part 381a-2 is connected with the connection part 391-2 of the Logic chip 312A-2.

According to such a configuration, in the chip stacked wafer 300D in FIG. 18, the internal circuit 361-31 of the Logic chip 312A-1 and the internal circuit 361-32 of the Logic chip 312A-2 are electrically connected with the connection part 391-1, the connection part 381a-1, the connection wiring 381, the connection part 381a-2, and the connection part 391-2 interposed therebetween.

As a result, a chip stacked wafer 301D having the CoW structure of the three layers in FIG. 18 can also electrically connect the DUT 344 of the Logic chip 312A-1 and the unillustrated inspection device by connecting the probe to the terminal 321a, and consequently can implement DUT measurement.

Furthermore, the internal circuits 361-31 and 361-32 of the two Logic chips 312A-1 and 312A-2 are connected by the connection wiring 381, and consequently can send and receive data and signals to and from each other.

Note that the connection wiring 381 that connects the Logic chip 312A-1 and 312A-2 may not only be formed in the inter-layer insulating film 371 of the intermediate layer 302, but also be formed at the boundary between the wafer 301 and the intermediate layer 302, or be formed in the substrate 345-1 of the intermediate layer 302.

### 13. TENTH MODIFIED EXAMPLE

Although the example has been described above where DUT measurement is implemented with respect to the one DUT 344, a plurality of DUTs may be provided, and may be able to be switched to perform DUT measurement.

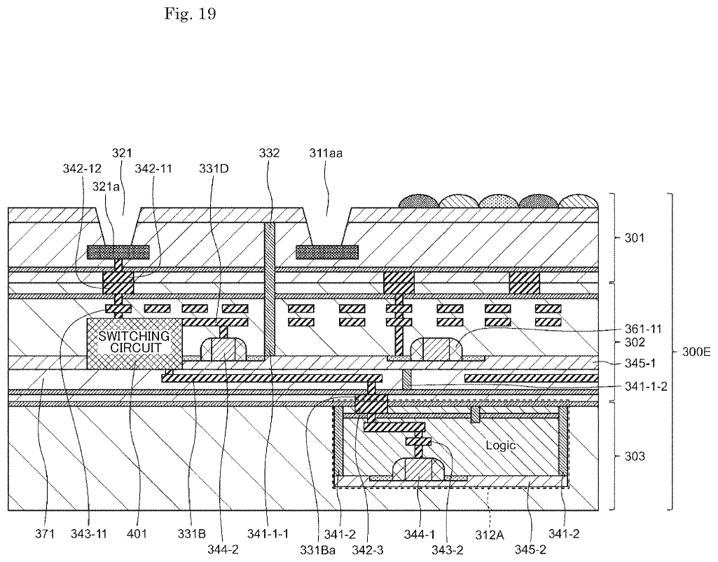

FIG. 19 illustrates a configuration example of a chip stacked wafer of a CoW structure that enables DUT measurement by switching between two DUTs.

A chip stacked wafer 300E in FIG. 19 employs a configuration where, in addition to the DUT 344 of the Logic layer 303 in the chip stacked wafer 300B in FIG. 16, the DUT 344 is also added to the intermediate layer, and can implement DUT measurement by switching between the DUTs 344 by a switching circuit 401.

Note that, in FIG. 19, the configuration of the chip stacked wafer 300B in FIG. 16 is adopted as the basic configuration, and the DUT of the Logic layer 303 will be referred to as a DUT 344-1 and the DUT of the intermediate layer 302 will be referred to as a DUT 344-2.

Furthermore, the configuration of the DUT 344-1 of the Logic layer 303 after the connection wiring 331B is the same as that of the chip stacked wafer 300B illustrated in FIG. 16, and therefore description thereof will be omitted.

That is, in the chip stacked wafer 300E in FIG. 18, the difference from the chip stacked wafer 300B in FIG. 16 is that the intermediate layer 304 is provided with the switching circuit 401, a connection wiring 331D, and the DUT 344-2.

The switching circuit 401 is connected with the wiring 343-11 and the connection wirings 331B and 331D. That is, the switching circuit 401 employs a configuration where the switching circuit 401 is connected with the terminal 321a with the connection parts 342-11 and 342-12 and the wiring 343-11 interposed therebetween, and the terminal 321a is connected with the probe to enable the unillustrated inspection device to be connected thereto. Furthermore, when being electrically connected with the inspection device, the switching circuit 401 is controlled by the inspection device, and the DUTs 344-1 and 344-2 that are DUT measurement targets are switched based on an instruction from the inspection device to implement DUT measurement.

More specifically, when receiving an instruction to set the DUT 344-1 as the DUT measurement target, the switching circuit 401 sets the DUT 344-1 of the Logic chip 312A of the Logic layer 303 as a measurement object and implement DUT measurement via the connection wiring 331B, the connection part 331Ba, the connection part 342-3, and the wiring 343-2.

Furthermore, when receiving an instruction to set the DUT 344-2 as the DUT measurement target, the switching circuit 401 sets the DUT 344-2 of the intermediate layer 302 as the measurement target and implement DUT measurement via the connection wiring 331D.

As a result, the chip stacked wafer 300E having the CoW structure of the three layers illustrated in FIG. 19 can switch between the DUT 344-1 of the Logic chip 312A-1 in the Logic layer 303 and the DUT 344-2 of the intermediate layer 302 by connecting the probe to the terminal 321a, whereby DUT measurement is enabled.

Note that the present disclosure can also employ a following configuration.
<1> A semiconductor device includes:
a first semiconductor chip that includes an imaging element;
a second semiconductor chip that is different from the first semiconductor chip; and
a connection wiring that electrically connects an internal circuit, which is a circuit in the second semiconductor chip,
with a terminal outside the second semiconductor chip or an external circuit, which is a circuit outside the second semiconductor chip.
<2> In the semiconductor device described in <1>, the terminal is a terminal formed in a scribe that is at a position at which the scribe is cut by a cutting blade when the semiconductor device is singulated from a wafer, on which the semiconductor device has been formed in a manufacturing process.
<3> In the semiconductor device described in <2>, the terminal is formed in the scribe at a time when the semiconductor device manufactured by stacking the singulated second semiconductor chip on the first semiconductor chip formed on the wafer is singulated from the wafer in the manufacturing process.
<4> In the semiconductor device described in <2>, the first semiconductor chip has an end part, surroundings of which are surrounded by a guard ring, and the scribe is formed on an outer side of the guard ring.
<5> In the semiconductor device described in <1>, the second semiconductor chip has an end part, surroundings of which are at least partially surrounded by a guard ring, and the internal circuit is formed on an outer side of the guard ring.
<6> In the semiconductor device described in <1>, the second semiconductor chip has an end part, surroundings of which are at least partially surrounded by a guard ring, and the internal circuit is formed on an inner side of the guard ring.
<7> In the semiconductor device described in <6>, the second semiconductor chip has an end part, surroundings of which are at least partially surrounded by a guard ring, and the internal circuit is formed on an inner side of the guard ring and, moreover, on an inner side surrounded by a seal ring.
<8> In the semiconductor device described in <1>, the connection wiring is formed in an insulating film in the first semiconductor chip.
<9> In the semiconductor device described in <8>, the connection wiring is formed in a bonding interface between the first semiconductor chip and the second semiconductor chip.
<10> In the semiconductor device described in <8>, the connection wiring is surrounded by a guard ring in at least part of surroundings.
<11> In the semiconductor device described in <8>, the connection wiring is sandwiched by water resistant films having water resistance at least in one of a front stage and a rear stage in an incident direction of incident light with respect to an imaging plane of the imaging element.
<12> In the semiconductor device described in <8>, the connection wiring is formed so as to sandwich the first semiconductor chip and the second semiconductor chip.
<13> The semiconductor device described in <1> further includes an intermediate layer between a first layer including the first semiconductor chip and a second layer including the second semiconductor chip, and
the connection wiring is formed in the intermediate layer.
<14> In the semiconductor device described in <13>, the connection wiring is formed in a substrate of the intermediate layer.
<15> In the semiconductor device described in <13>, the connection wiring is formed in an insulating film of the intermediate layer.
<16> In the semiconductor device described in <15>, the connection wiring connects the internal circuit formed in the second layer and the external circuit in the second layer.
<17> In the semiconductor device described in <16>, the external circuit in the second layer is an internal circuit that is formed in the second layer and included in a third semiconductor chip different from the second semiconductor chip.
<18> In the semiconductor device described in <1>, the second semiconductor chip includes a first internal circuit and a second internal circuit different from the first internal circuit as the internal circuits, and
the connection wiring includes
a first connection wiring that electrically connects the first internal circuit in the second semiconductor chip and the terminal outside the second semiconductor chip, and
a second connection wiring that electrically connects the second internal circuit in the second semiconductor chip and the external circuit that is the circuit outside the second semiconductor chip.
<19> In the semiconductor device described in <1>,
the internal circuit is a test device of the second semiconductor chip, and
an inspection device that inspects an operating state of the second semiconductor chip is electrically connected with the terminal, with a probe being interposed therebetween and thereby is electrically connected with the test device, with the terminal and the connection wiring being interposed therebetween, and controls the test device to inspect the operating state of the second semiconductor chip.
<20> The semiconductor device described in <19> further includes:
another test device that tests another circuit different from the test device of the second semiconductor chip;
another connection wiring that is different from the connection wiring connected with the other test device; and
a switching unit that is connected with the terminal, the connection wiring, and the other connection wiring, and switches over whether to connect the terminal and the test device via the connection wiring, or connect the terminal and the other test device via the other connection wiring.

### REFERENCE SIGNS LIST

100, 100A to 100D Chip stacked wafer
101 Wafer
102 Logic layer
110 Solid-state imaging device
111a Solid-state imaging element
111aa Terminal
111ab Color filter
112A Logic chip
121 Scribe
121a Terminal
131 Connection wiring
131a Connection part
141 Guard ring
142 Connection part
143 Wiring
144 DUT
145 Substrate
146 Buried film
161, 162 Water resistant layer
171, 171′ Water resistant layer
191, 191A, 191B Probe
251 Water resistant layer
261 Seal ring
282 Connection wiring
282a Connection part
291 Connection part
300, 300A to 300E Chip stacked wafer
301 Wafer
302 Intermediate layer
303 Logic layer
311aa Terminal
321 Scribe
321a Terminal
331, 331A to 331D Connection wiring
331a, 331Aa to 331Da Connection part
344, 344-1, 344-2 DUT
381 Connection wiring

What is claimed is:

1. A semiconductor device, comprising:
a first semiconductor chip that includes an imaging element;
a second semiconductor chip that is different from the first semiconductor chip; and
a connection wiring that electrically connects an internal circuit, which is a circuit in the second semiconductor chip,
with a terminal outside the second semiconductor chip or an external circuit, which is a circuit outside the second semiconductor chip.

2. The semiconductor device according to claim 1, wherein the terminal is a terminal formed in a scribe that is at a position at which the scribe is cut by a cutting blade when the semiconductor device is singulated from a wafer, on which the semiconductor device has been formed in a manufacturing process.

3. The semiconductor device according to claim 2, wherein the terminal is formed in the scribe at a time when the semiconductor device manufactured by stacking the singulated second semiconductor chip on the first semiconductor chip formed on the wafer is singulated from the wafer in the manufacturing process.

4. The semiconductor device according to claim 2, wherein the first semiconductor chip has an end part, surroundings of which are surrounded by a guard ring, and the scribe is formed on an outer side of the guard ring.

5. The semiconductor device according to claim 1, wherein the second semiconductor chip has an end part, surroundings of which are at least partially surrounded by a guard ring, and the internal circuit is formed on an outer side of the guard ring.

6. The semiconductor device according to claim 1, wherein the second semiconductor chip has an end part, surroundings of which are at least partially surrounded by a guard ring, and the internal circuit is formed on an inner side of the guard ring.

7. The semiconductor device according to claim 6, wherein the second semiconductor chip has an end part, surroundings of which are at least partially surrounded by a guard ring, and the internal circuit is formed on an inner side of the guard ring and, moreover, on an inner side surrounded by a seal ring.

8. The semiconductor device according to claim 1, wherein the connection wiring is formed in an insulating film in the first semiconductor chip.

9. The semiconductor device according to claim 8, wherein the connection wiring is formed in a bonding interface between the first semiconductor chip and the second semiconductor chip.

10. The semiconductor device according to claim 8, wherein the connection wiring is surrounded by a guard ring in at least part of surroundings.

11. The semiconductor device according to claim 8, wherein the connection wiring is sandwiched by water resistant films having water resistance at least in one of a front stage and a rear stage in an incident direction of incident light with respect to an imaging plane of the imaging element.

12. The semiconductor device according to claim 8, wherein the connection wiring is formed so as to sandwich the first semiconductor chip and the second semiconductor chip.

13. The semiconductor device according to claim 1, further comprising an intermediate layer between a first layer including the first semiconductor chip and a second layer including the second semiconductor chip, wherein the connection wiring is formed in the intermediate layer.

14. The semiconductor device according to claim 13, wherein the connection wiring is formed in a substrate of the intermediate layer.

15. The semiconductor device according to claim 13, wherein the connection wiring is formed in an insulating film of the intermediate layer.

16. The semiconductor device according to claim 15, wherein the connection wiring connects the internal circuit formed in the second layer and the external circuit in the second layer.

17. The semiconductor device according to claim 16, wherein the external circuit in the second layer is an internal circuit that is formed in the second layer and included in a third semiconductor chip different from the second semiconductor chip.

18. The semiconductor device according to claim 1, wherein
the second semiconductor chip includes a first internal circuit and a second internal circuit different from the first internal circuit, as the internal circuits, and
the connection wiring includes
a first connection wiring that electrically connects the first internal circuit in the second semiconductor chip and the terminal outside the second semiconductor chip, and
a second connection wiring that electrically connects the second internal circuit in the second semiconductor chip and the external circuit that is the circuit outside the second semiconductor chip.

19. The semiconductor device according to claim 1, wherein
the internal circuit is a test device of the second semiconductor chip, and
an inspection device that inspects an operating state of the second semiconductor chip is electrically connected with the terminal, with a probe being interposed therebetween and thereby is electrically connected with the test device, with the terminal and the connection wiring being interposed therebetween, and controls the test device to inspect the operating state of the second semiconductor chip.

20. The semiconductor device according to claim 19, further comprising:
another test device that tests another circuit different from the test device of the second semiconductor chip;
another connection wiring that is different from the connection wiring connected with the other test device; and
a switching unit that is connected with the terminal, the connection wiring, and the other connection wiring, and switches over whether to connect the terminal and the test device via the connection wiring, or connect the terminal and the other test device via the other connection wiring.
